(19) United States
(12) Patent Application Publication
(10) Pub. No.: US 2026/0114207 A1
(43) Pub. Date: Apr. 23, 2026

(54) EXHAUST UNIT AND SUBSTRATE PROCESSING APPARATUS HAVING THE SAME

(71) Applicant: SEMES CO., LTD., Cheonan-si (KR)

(72) Inventors: Daeyong DO, Cheonan-si (KR); Seokho Son, Cheonan-si (KR)

(73) Assignee: SEMES CO., LTD., Cheonan-si (KR)

(21) Appl. No.: 19/347,407

(22) Filed: Oct. 1, 2025

(30) Foreign Application Priority Data
Oct. 22, 2024 (KR) 10-2024-0144584

(51) Int. Cl. H01L 21/67

(52) U.S. Cl. CPC H10P 72/0402; C23C 16/4408; C23C 16/455

(57) ABSTRACT

An exhaust unit includes a housing configured to provide an inflow space into which byproducts generated during a substrate processing process are introduced; a byproduct inlet portion including at least one inlet port provided in an open upper surface of the housing and having a structure that partially opens the inflow space so that the byproducts are introduced into the inflow space, the byproduct inlet portion including a plurality of piece plates that respectively cover open regions, excluding the open region in which the at least one inlet port is provided, among a plurality of open regions of the open upper surface of the housing; and a byproduct exhaust portion having a hole structure provided on a portion of a lower surface of the housing so as to exhaust the byproducts introduced into the inflow space of the housing through the byproduct inlet portion, to the outside.

### PRIORITY STATEMENT

This application claims priority under 35 U.S.C. § 119 to Korean Patent Application No. 10-2024-0144584, filed on Oct. 22, 2024 in the Korean Intellectual Property Office (KIPO), the contents of which are herein incorporated by reference in their entirety.

### BACKGROUND

### 1. Field

Example embodiments relate to an exhaust unit and a substrate processing apparatus including the same. More particularly, example embodiments relate to an exhaust unit for exhausting byproducts generated during a processing process performed on a substrate, and a substrate processing apparatus including the same.

### 2. Description of the Related Art

In the manufacturing of integrated circuit devices such as semiconductor devices and display devices, processing processes may be performed on the substrate. Examples of such processing processes include a coating process in which photoresist is applied to the substrate; a developing process in which a developer is sprayed onto the substrate to develop the photoresist applied to the substrate; a cleaning process in which a cleaning solution is sprayed onto the substrate to clean the substrate; and a drying process in which the cleaning solution sprayed onto the substrate is dried.

These processing processes may generate byproducts such as mist, fumes, and particles. If these byproducts are not sufficiently exhausted from the substrate and remain around the substrate, they may be absorbed by the substrate, potentially resulting in process defects. Therefore, conventional processing devices for performing these processes are equipped with exhaust units to exhaust the byproducts generated during the processing process.

### SUMMARY

Example embodiments provide an exhaust unit having a structure with variable exhaust positions that exhausts byproducts generated during a processing process.

Example embodiments provide a substrate processing apparatus having the exhaust unit.

According to example embodiments, an exhaust unit includes a housing configured to provide an inflow space into which byproducts generated during a substrate processing process are introduced; a byproduct inlet portion including at least one inlet port provided in an open upper surface of the housing and having a structure that partially opens the inflow space so that the byproducts are introduced into the inflow space, the byproduct inlet portion including a plurality of piece plates that respectively cover open regions, excluding the open region in which the at least one inlet port is provided, among a plurality of open regions of the open upper surface of the housing; and a byproduct exhaust portion having a hole structure provided on a portion of a lower surface of the housing so as to exhaust the byproducts introduced into the inflow space of the housing through the byproduct inlet portion, to the outside.

In example embodiments, the housing may be disposed at a lower portion of the process chamber where the processing process is performed, the byproduct inlet portion may be disposed at the lower portion of the process chamber toward the interior of the process chamber, and the byproduct exhaust portion may be disposed at the lower portion of the process chamber toward the exterior, or/and the housing may be disposed at an upper portion of the process chamber where the processing process is performed, the byproduct inlet portion may be disposed at the upper portion of the process chamber toward the interior of the process chamber, and the byproduct exhaust portion may be disposed at the upper portion of the process chamber toward the exterior.

In example embodiments, the plurality of open regions may be provided to have a checkerboard arrangement.

In example embodiments, the at least one inlet port may be provided with a flow path that provides a path for the byproduct to flow into the inflow space, and the at least one inlet port may have an opening/closing member that selectively opens and closes the flow path.

In example embodiments, the plurality of open regions may have the same size, and the inlet port may have a size that covers each of the open regions of the same size.

According to example embodiments, a substrate processing apparatus includes a process chamber configured to provide a processing space for performing a processing process on a substrate, a transport unit configured to transfer the substrate to the process chamber, an injection unit configured to spray a fluid toward the substrate transferred to the process chamber by the transport unit, and an exhaust unit configured to exhaust byproducts generated by spraying the fluid during the processing process, to the outside of the process chamber. The exhaust unit includes a housing configured to provide an inflow space into which the byproducts are introduced; a byproduct inlet portion including at least one inlet port provided in an open upper surface of the housing and having a structure that partially open the inflow space so that the byproducts are introduced into the inflow space, the byproduct inlet portion including a plurality of piece plates that are provided to cover open regions, excluding the open region in which the at least one inlet port is provided, among a plurality of open regions constituting the open upper surface of the housing; and a byproduct exhaust portion having a hole structure provided in a portion of a lower surface of the housing so as to exhaust the byproduct introduced into the inflow space of the housing through the byproduct inlet portion, to the outside.

In example embodiments, the transport unit may be configured to transfer the substrate by rotational driving of a roller in contact with a backside surface of the substrate, or to transfer the substrate while the substrate is levitated.

In example embodiments, the injection unit may be configured to spray a fluid toward a front surface of the substrate, to spray a fluid toward a backside surface of the substrate, or to spray a fluid toward both of the front and backside surfaces of the substrate.

In example embodiments, the injection unit may be arranged diagonally at a predetermined angle relative to a vertical direction perpendicular to the transport direction of the substrate, and is configured to have a length that covers from one end of the substrate to the other end in the diagonal arrangement.

In example embodiments, the injection unit may be configured to inject a fluid toward the substrate while tilted at a predetermined angle toward the direction in which the substrate is transported.

In example embodiments, the exhaust unit may be positioned in front of the injection unit with respect to the direction in which the substrate is transported.

In example embodiments, the housing of the exhaust unit may be disposed at a lower portion of the process chamber, the byproduct inlet portion may be disposed at the lower portion of the process chamber toward the interior of the process chamber, and the byproduct exhaust portion may be disposed at the lower portion of the process chamber toward the exterior, or/and the housing may be disposed at an upper portion of the process chamber, the byproduct inlet portion may be disposed at the upper portion of the process chamber toward the interior of the process chamber, and the byproduct exhaust portion may be disposed at the upper portion of the process chamber toward the exterior.

In example embodiments, the plurality of open regions in the exhaust unit may be arranged to have a checkerboard arrangement.

In example embodiments, the at least one inlet port may have a flow path formed therein that provides a path for the byproduct to flow into the inflow space, and the at least one inlet portion may have an opening/closing member that selectively opens and closes the flow path.

In example embodiments, the plurality of open regions in the exhaust unit may have the same size, and the inlet port may have a size that covers each of the open regions of the same size.

According to example embodiments, a substrate processing apparatus includes a process chamber configured to provide a processing space in which a substrate is dried; a transport unit configured to transfer the substrate to the process chamber, the transport unit configured to transfer the substrate by driving of a roller in contact with a backside surface of the substrate; an injection unit configured to spray a drying gas toward the substrate transferred to the process chamber by the transport unit, the injection unit being arranged diagonally at a predetermined angle relative to a vertical direction perpendicular to the transport direction of the substrate, the injection unit configured to have a length that covers the substrate from one end to the other end in the diagonal arrangement, the injection unit configured to spray the drying gas toward the substrate while being tilted at a predetermined angle toward the direction in which the substrate is transported; and an exhaust unit configured to exhaust byproducts generated by spraying the drying gas during the drying process, to the outside of the process chamber, the exhaust unit configured to be positioned in front of the spray unit with respect to the transport direction of the substrate. The exhaust unit includes a housing configured to provide an inflow space into which the byproducts are introduced; a byproduct inlet portion including at least one inlet port provided in an open upper surface of the housing and having a structure that partially open the inflow space so that the byproducts are introduced into the inflow space, the byproduct inlet portion including a plurality of piece plates that are provided to cover open regions, excluding the open region in which the at least one inlet port is provided, among a plurality of open regions constituting the open upper surface of the housing; and a byproduct exhaust portion having a hole structure in a portion of a bottom surface of the housing so as to exhaust the byproduct introduced into the inflow space of the housing through the byproduct inlet portion, to the outside.

In example embodiments, the injection unit may be configured to spray a fluid toward a front surface of the substrate, toward the backside surface of the substrate, or toward both of the front and backside surfaces of the substrate.

In example embodiments, the housing of the exhaust unit may be disposed at a lower portion of the process chamber, the byproduct inlet portion may be disposed at the lower portion of the process chamber toward the interior of the process chamber, and the byproduct exhaust may be disposed at the lower portion of the process chamber toward the exterior, or/and the housing may be disposed at an upper portion of the process chamber, the byproduct inlet portion may be disposed at the upper portion of the process chamber toward the interior of the process chamber, and the byproduct exhaust may be disposed at the upper portion of the process chamber toward the exterior.

In example embodiments, the plurality of open regions of the exhaust unit may be arranged to have a checkerboard arrangement.

In example embodiments, the plurality of open regions in the exhaust unit may have the same size, and the inlet port may be formed with a flow path that provides a path for the byproduct to flow into the inflow space, and the inlet port may be sized to selectively cover each of the open regions of the same size.

According to example embodiments, an exhaust unit and a substrate processing apparatus may vary a position of each of inlet ports that has a structure that partially opens an inflow space into which byproducts are introduced, thereby varying an exhaust position for exhausting the byproducts generated during a processing process. Accordingly, the exhaust unit and the substrate processing apparatus may change the exhaust position to a desired position even when a situation occurs in which air flow, etc. changes during the processing process, so that byproducts may be exhausted under optimal conditions.

Thus, the exhaust unit and the substrate processing apparatus according to example embodiments may exhaust the byproducts under optimal conditions during the processing process to thereby minimize process defects caused by the byproducts. Accordingly, the exhaust unit and the substrate processing apparatus according to example embodiments can be expected to improve process reliability in the manufacture of integrated circuit devices such as semiconductor devices and display devices.

### BRIEF DESCRIPTION OF THE DRAWINGS

Example embodiments will be more clearly understood from the following detailed description taken in conjunction with the accompanying drawings. FIGS. 1 to 4 represent non-limiting, example embodiments as described herein.

FIG. 1 is a cross-sectional view illustrating a substrate processing apparatus in accordance with example embodiments.

FIG. 2 is a plan view illustrating an exhaust unit of the substrate processing apparatus of FIG. 1.

FIG. 3 is a cross-sectional view illustrating the exhaust unit of FIG. 2.

FIG. 4 is a cross-sectional view illustrating a path providing portion in the exhaust unit of the substrate processing apparatus of FIG. 1.

### DETAILED DESCRIPTION OF EXAMPLE EMBODIMENTS

Hereinafter, example embodiments will be explained in detail with reference to the accompanying drawings.

Example embodiments may be embodied in many different forms and should not be construed as limited to example embodiments set forth herein. Rather, these example embodiments are provided so that this disclosure will be thorough and complete, and will fully convey the scope of example embodiments to those skilled in the art. In the drawings, the sizes and relative sizes of components or elements may be exaggerated for clarity. It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

It will be understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the present disclosure will be described in more detail with reference to the accompanying drawings. The same reference numerals will be used for the same elements in the drawings, and redundant descriptions of the same elements will be omitted.

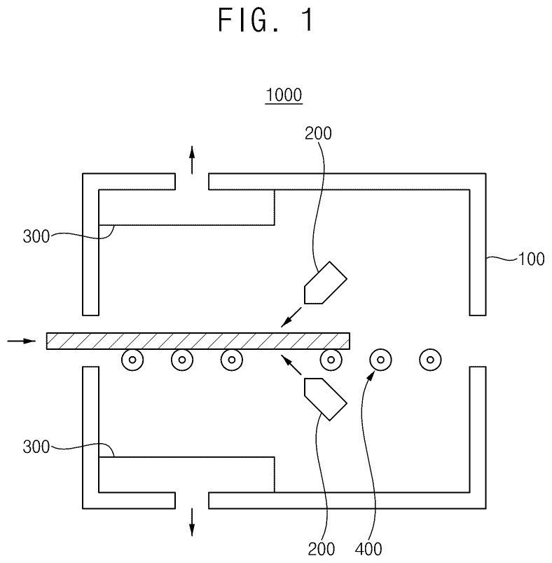

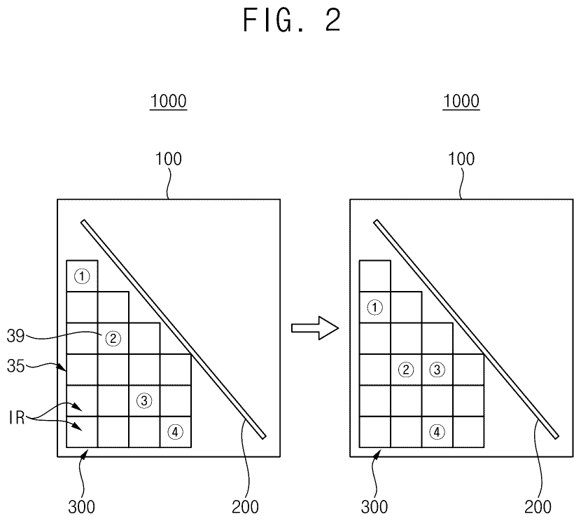

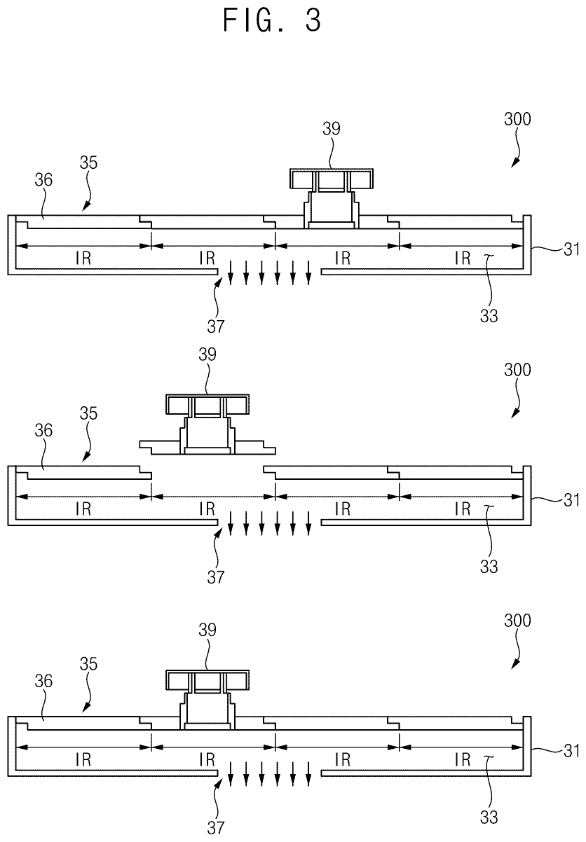

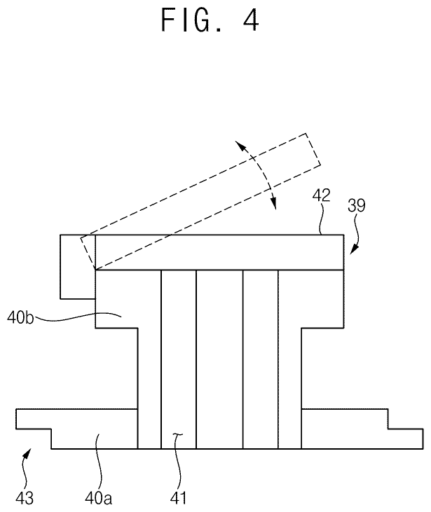

FIG. 1 is a cross-sectional view illustrating a substrate processing apparatus in accordance with example embodiments. FIG. 2 is a plan view illustrating an exhaust unit of the substrate processing apparatus of FIG. 1. FIG. 3 is a cross-sectional view illustrating the exhaust unit of FIG. 2. FIG. 4 is a cross-sectional view illustrating a path providing portion in the exhaust unit of the substrate processing apparatus of FIG. 1.

First, referring to FIG. 1, the substrate processing apparatus 1000 according to example embodiments may be applied to a processing process for manufacturing integrated circuit devices such as semiconductor devices and display devices. The processing process for manufacturing an integrated circuit device may be performed by spraying a fluid toward a substrate. Examples of the processing process may include a coating process for applying photoresist onto a substrate, a developing process for spraying a developer onto the substrate and developing the photoresist applied onto the substrate, a cleaning process for spraying a cleaning solution onto the substrate and cleaning the substrate, and a drying process for spraying a drying gas onto the substrate and drying the cleaning solution sprayed onto the substrate. In addition, examples of the processing process may include a thin film process for forming a thin film on a substrate, a discharge process for discharging ink liquid such as R, G, and B ink on a substrate, etc.

In example embodiments, the substrate processing apparatus 1000 may include a process chamber 100, a transport unit 400, an injection unit 200, an exhaust unit 300, etc.

The process chamber 100 may provide a processing space where a processing process is performed. A processing atmosphere suitable for processing conditions of the processing process may be generated within the processing space of the process chamber 100. The process chamber 100 may additionally be equipped with components for generating the processing atmosphere, such as temperature and pressure conditions, that meets the predetermined processing conditions. Furthermore, the process chamber 100 may be configured to have a sealed structure depending on the processing conditions.

During the processing process, a substrate on which the processing process is performed may be positioned within the processing space of the process chamber 100. The transport unit 400 may transport the substrate into the process chamber 100 so that the substrate may be positioned within the process chamber 100.

Here, the substrate on which the processing process is performed may be a wafer for manufacturing a semiconductor device. In this case, the transport unit may include a robot arm. The robot arm may be used to load a substrate into the process chamber 100 and unload the substrate from the process chamber 100. When the transport unit includes the robot arm, the process chamber 100 may be equipped with a mounting member, such as a substrate stage on which the substrate is mounted, and the robot arm may be configured to move from the outside to the inside of the process chamber 100 and from the inside to the outside of the process chamber 100 through a gate provided in the process chamber 100.

The substrate on which the processing process is performed may be a glass substrate for manufacturing a display device. In this case, the transport unit may have a structure that transports the substrate while levitating the substrate. For example, the process chamber 100 may be equipped with a levitation stage for levitating the substrate, and the transport unit may have a structure such as a gripper that grips one or both ends of the substrate and transports the substrate along the levitation stage. In addition, the transport unit may have a structure such as a transfer roller that contacts a backside surface of the substrate and transfers the substrate by rotational driving. As mentioned, when the transport unit has the structure in which the roller is rotationally driven or the structure in which the substrate is moved along the levitation stage, the transport unit may be located inside the process chamber 100.

The transport unit 400 may load a substrate into the process chamber 100 and unload the substrate from the process chamber 100. That is, the transport unit 400 may load a substrate into the process chamber 100, and after a processing process is performed on the loaded substrate, the transport unit 400 may unload the substrate from the process chamber 100. Here, the transport unit 400 having the structure for transporting the substrate along the levitation stage during the manufacture of the display device may be applied to a substrate processing apparatus for performing a coating process, a discharge process, a thin film process, etc., and the transport unit 400 having the structure for transporting the substrate by rotational driving of a roller may be applied to a substrate processing apparatus for performing a developing process, a cleaning process, a drying process, etc.

The injection unit 200 may be provided to inject a fluid toward a substrate while moving the substrate within the process chamber 100. Examples of the injection unit 200 may include an injector for injecting a fluid onto a substrate such as a wafer for manufacturing a semiconductor device, and may include a slit nozzle, an inkjet head, an air knife, etc. for injecting a fluid onto a substrate such as a glass substrate for manufacturing a display device. Here, when the injection unit 200 includes the injector, the fluid may be injected toward a substrate on a substrate stage within the process chamber 100 by the transport unit 400 such as a robot arm. When the injection unit 200 includes the slit nozzle, the inkjet head, or the air knife, the fluid may be injected toward a substrate while moving the substrate within the process chamber 100 by the transport unit 400 having the structure in which the roller rotates and is driven or the structure in which the substrate is moved along the levitation stage.

The spray unit 200 including the injector may be configured to spray a fluid such as a photoresist, a cleaning solution, etc., onto the central region of the substrate. In this case, the substrate may be rotated using a spin chuck or the like. Accordingly, the fluid sprayed onto the central region of the substrate may be evenly sprayed onto the entire region of the substrate by spreading to the peripheral region of the substrate due to centrifugal force as the substrate rotates.

The spray unit 200 including the slit nozzle may be configured to spray a fluid, such as a photoresist or a cleaning solution, toward the substrate. In this case, the spray unit may be arranged to extend along a width direction perpendicular to the moving direction of the substrate, and in particular, may have a length sufficient to cover the width direction length of the substrate. Accordingly, the spray unit, such as the slit nozzle, may spray the fluid along the width direction of the substrate while being transported by the transport unit 400, thereby allowing the fluid to be evenly sprayed over the entire region of the substrate.

The spray unit 200 including the inkjet head may be configured to spray a fluid, such as R, G, or B ink, toward the substrate. In this case, the spray unit may be arranged to extend along a width direction perpendicular to the moving direction of the substrate, and in particular, may have a structure that moves along an extension direction of a gantry while being supported by the gantry that extends along the width direction of the substrate. Accordingly, the spray unit, such as the inkjet head, may spray a fluid onto a desired local region of the substrate while moving along the extension direction of the gantry along the width direction of the substrate being transported by the transport unit 400.

The spray unit 200 including the air knife may be provided to spray a fluid, such as a drying gas, toward the substrate. As illustrated in FIG. 2, the spray unit, such as the air knife, may be arranged diagonally at a predetermined angle relative to a width direction perpendicular to the moving direction of the substrate. That is, the spray unit, such as the air knife, may be arranged diagonally at a predetermined angle between the moving direction of the substrate and a horizontal direction perpendicular to the moving direction. In addition, the spray unit, such as the air knife, may have a length that covers the width direction of the substrate from one end to the other end when arranged diagonally. Accordingly, the spray unit, such as the air knife, may spray the fluid over a relatively longer diagonal length compared to the width direction of the substrate being transported by the transport unit 400, thereby allowing the fluid to be evenly sprayed onto the substrate over a relatively larger region than the entire surface of the substrate. In this way, arranging the spray unit 200 diagonally may be advantageous in spraying a sufficient amount of fluid onto the substrate. The injection unit 200 may be configured to inject a fluid toward a front surface of the substrate, to inject a fluid toward a backside surface of the substrate, or to inject a fluid toward both the front and backside surfaces of the substrate. When the injection unit 200 is configured to inject a fluid toward the front surface of the substrate, examples of the injection unit may be an injector, a slit nozzle, etc. for applying photoresist, an injector, a slit nozzle, etc. for injecting a cleaning solution, or an inkjet head, etc. for injecting R, G, and B ink. When the injection unit 200 is configured to inject fluid a toward the backside surface of the substrate, examples of the injection unit may be a slit nozzle, etc. for injecting a cleaning solution, or an air knife, etc. for injecting a drying gas. When the injection unit 200 is configured to inject a fluid toward both the front and backside surfaces of the substrate, examples of the injection unit may be a slit nozzle, etc. for injecting a cleaning solution, or an air knife, etc. for injecting a drying gas.

The injection unit 200 may be provided to inject a fluid toward the substrate in a vertical direction perpendicular to the surface of the substrate. By injecting the fluid in the direction perpendicular to the moving direction of the substrate, the fluid may be injected at a more precise location, and examples of the injection unit may include an injector or slit nozzle for applying photoresist, or an inkjet head for injecting R, G, or B ink. The injection unit 200 may be provided to inject the fluid toward the substrate while being inclined at a predetermined angle toward the direction in which the substrate is transported. By injecting the fluid at a predetermined angle relative to the transport direction of the substrate, a larger amount of fluid may be injected onto the substrate and a fluid with a relatively strong force may be injected onto the substrate, and examples of the injection unit may include a slit nozzle for injecting a cleaning solution, or an air knife for injecting a drying gas.

As mentioned above, when performing the above processing process, the injection unit 200 may be configured to inject a fluid toward the substrate being transported to the processing chamber 100 by the transport mechanism (transport unit). When performing the above processing process, byproducts such as mist, fume, particles, etc. may be generated due to the injection of the fluid. Byproducts such as mist, fume, etc. may be generated primarily by injecting fluids such as photoresist, cleaning solution, R, G, B ink, etc., and byproducts such as particles, etc. may be generated primarily by injecting fluids such as cleaning solution, drying gas, etc.

The exhaust unit 300 may be provided to exhaust byproducts generated by the injection of fluid during a processing process to the outside of the process chamber 100. In example embodiments, the exhaust unit 300 may include a housing 31, a byproduct inlet portion 35, a byproduct exhaust portion 37, etc.

The housing 31 may be provided to provide an inflow space 33 into which byproducts are introduced. The housing 31 may have different sizes and shapes depending on the size and shape of the process chamber 100. The housing 31 may include a plurality of side walls that define the inflow space 33 and are connected to each other. When viewed in plan view, the plurality of side walls may have a polygonal shape, such as a triangle or a square, or a circular shape.

The byproduct inlet portion 35 may be provided with a structure that opens or exposes at least a portion of the inflow space 33 in an open upper surface of the housing 31 so that byproducts may be introduced into the inflow space 33. The byproduct inlet portion 35 may have a structure in which at least one inlet port 39 is provided on the upper surface of the housing 31. The at least one inlet port 39 may be provided as a path providing portion that provides a path for flow (movement) from the processing space of the process chamber 100 to the inflow space 33.

The open upper surface of the housing may include a plurality of open regions (IR). The inlet port 39 may be installed in a selected open region (IR) among the plurality of open regions (IR). The byproduct inlet portion 35 may include a plurality of piece plates 36 that respectively cover the remaining open regions (IR) except for the open region (regions \textcircled{1}, \textcircled{2}, \textcircled{3}, and \textcircled{4} in FIG. 2) in which the inlet port 39 is installed.

Each of the plurality of open regions may have the same size. While the shape of each of the plurality of open regions is not limited, it may primarily have a square structure. For example, the plurality of open regions may have a checkerboard arrangement or a tiled layout.

The plurality of piece plates 36 may be installed to cover selected open regions of the plurality of open regions (IR). The byproduct inlet portion 35 may include the inlet port 39 that is provided in one open region exposed by the plurality of piece plates 36 in the open upper surface of the housing 31 and provides a path for movement to the inflow space 33. In particular, the byproduct inlet portion 35 may have a plurality of inlet ports, and each of the inlet ports may be provided to enable selective opening.

As described above, the byproduct inlet portion 35 may include the at least one inlet port 39 that may be selectively opened to allow the inflow of byproduct into the inflow space 33. In particular, the byproduct inlet portion 35 may be provided with a structure that partially opens and selectively opens the inflow space 33 on the open upper surface of the housing 31, and the structure may include a plurality of inlet ports 39.

The byproduct exhaust portion 37 may be provided with a structure that exhausts the byproduct from the inflow space 33 of the housing 31 to the outside. That is, the byproduct exhaust portion 37 may exhaust the byproduct that is introduced into the inflow space 33 of the housing 31 through the byproduct inlet portion 35, to the outside of the housing 31. The byproduct exhaust portion 37 may be arranged to face the byproduct inlet portion 35, and considering the relative advantage of exhausting the byproduct, the relative advantage of connecting to an exhaust line (not illustrated) described later, etc., the byproduct exhaust portion 37 may be provided in a portion of a bottom surface (bottom wall) of the housing 31 rather than a portion of a side surface (side wall) of the housing 31. Accordingly, the byproduct exhaust portion 37 may be provided with a hole structure in a portion of the bottom surface of the housing 31. The number of the hole structures of the byproduct exhaust portion 37 may not be limited. However, when a single hole is provided as the byproduct exhaust portion 37, it may be provided in the central region of the bottom surface of the housing 31. When a plurality of the byproduct exhaust portions 37 are provided, a plurality of holes corresponding toe the plurality of the byproduct exhaust portions 37 may be provided to have a radial structure extending from the central region of the bottom surface of the housing 31 to the peripheral region.

The hole formed as a portion of the byproduct exhaust portion 37, i.e., the exhaust hole, may be connected to the exhaust line. In addition, the exhaust line connected to the byproduct exhaust portion 37 may be connected to a negative pressure providing member such as a vacuum pump to enable vacuum suction.

Accordingly, the exhaust unit 300 may be provided to allow byproducts to be introduced into the inflow space 33 through the byproduct inlet portion 35 and to exhaust the byproducts introduced into the inflow space 33 to the outside through the byproduct exhaust port 37. In particular, the exhaust unit 300 may be provided to have a structure that partially opens and selectively opens the inflow space 33, and further, may be configured to forcibly exhaust the byproducts introduced into the inflow space 33 to the outside through vacuum suction using a vacuum pump or the like.

The inlet port 39 as the path providing portion may be formed with a flow path 41 that provides a path for the by-products to be introduced into the inflow space 33 so that the by-products can be introduced into the inflow space 33. The inlet port 39 may include an opening/closing member that may selectively close the flow path so that the flow path can be selectively opened. For example, as illustrated in FIG. 4, the opening/closing member may include an opening/closing plate 42 for selectively blocking an inlet of the flow path 41. Alternatively, the opening/closing member may include an ON/OFF valve for opening and closing the flow path 41. One or more flow paths 41 may be formed. A size of the flow path 41 may vary depending on a size of the byproduct, and may be formed to have a diameter greater than a byproduct having a maximum manageable size.

When the fluid sprayed toward the substrate during the processing process flows into the inflow space 33, this may cause changes in the process conditions established within the process chamber 100, which may result in process defects during the processing. Therefore, the exhaust unit 300 may be configured not to simply open the inlet port, but rather to have a structure that minimizes the inflow of fluid into the inflow space 33 during the processing process by applying the inlet port 39 as the path providing portion.

As mentioned above, the plurality of open regions may be configured to have the same size, and the inlet ports 39 as the path providing portions may have the same size to cover the corresponding open regions. If the open regions have different sizes, the inlet ports 39 as the path providing portions must also have different sizes, which may be relatively disadvantageous from management and maintenance perspective.

The inlet port 39 as a path providing portion may be detachably provided in the open region (IR) defined on the open upper surface of the housing 31, similarly to the piece plates 36. The inlet port 39 may include a base plate 40a having the same size and shape as the piece plate 36 and a port body 40b provided on the base plate 40a and extending upward. The flow path 41 may be formed in the port body 40b. For example, the inlet port and the piece plates may be made to be detachable by moving the puzzle structure, and may also be more firmly fixed by force-fitting, screw fastening, etc., as needed. Reference numeral 43 may represent a recessed portion that is provided in an edge of the base plate 40a and fitted into a recessed portion provided in an edge of adjacent piece plate 36.

The exhaust unit 300 may include the inlet port 39 in which the flow path 41 is formed that provides a path for byproducts to flow into the inflow space 33, and may particularly be provided with the opening/closing member for selectively opening the flow path 41. Additionally, since the open regions are provided to have the same size, the inlet port 39 as the path providing portion may have a structure that covers each open region of the same size.

Further, during the process of vacuum drying the photoresist applied on the substrate, byproducts such as fumes may be generated. In this case, the exhaust unit 300 may be applied to exhaust the byproducts. That is, the exhaust unit 300 may be applied to exhaust the byproducts in a processing apparatus that is not equipped with an injection unit 200.

The exhaust unit 300 may be disposed at a lower portion of the process chamber 100. That is, the housing 31 of the exhaust unit 300 may be disposed at the lower portion of the process chamber 100. In this case, the byproduct inlet portion 35 may be disposed at the lower portion of the process chamber 100 toward the interior of the process chamber 100, and the byproduct exhaust 37 may be disposed at the lower portion of the process chamber 100 toward the exterior. Accordingly, the exhaust unit 300 disposed at the lower portion of the process chamber 100 may allow the byproduct to be introduced into the inflow space 33 from the lower portion of the process chamber 100 and may also allow the byproduct to be exhausted to the exterior through the bottom surface of the process chamber 100. The exhaust unit 300 may be disposed at an upper portion of the process chamber 100. That is, the housing 31 of the exhaust unit 300 may be disposed at the upper portion of the process chamber 100. In this case, the byproduct inlet portion 35 may be disposed at the upper portion of the process chamber 100 toward the interior of the process chamber 100, and the byproduct exhaust 37 may be disposed at the upper portion of the process chamber 100 toward the exterior. Accordingly, the exhaust unit 300 disposed at the upper portion of the process chamber 100 may allow the byproduct to be introduced into the inflow space 33 from the upper portion of the process chamber 100 and may also allow the byproduct to be exhausted to the exterior through an upper surface (top wall) of the process chamber 100. In addition, the exhaust unit 300 may be provided to be arranged at both the upper and lower portions of the process chamber 100.

As such, the exhaust unit 300 may be provided singly at the bottom or top of the process chamber 100, or may be provided at both the bottom and top of the process chamber 100. The placement of the exhaust unit 300 at the bottom and/or top within the process chamber 100 may vary depending on the type of fluid and the processing process. For example, in a processing apparatus for performing a cleaning process that sprays a cleaning solution or a drying process that sprays a drying gas, the exhaust unit 300 may be positioned at both the bottom and/or top of the process chamber 100.

Here, the byproduct exhaust port 37 with the hole structure within the exhaust unit 300 may be positioned at the bottom of the housing 31 because the exhaust unit 300 is positioned at the bottom or/and top of the process chamber 100. This is because, compared to a case where the byproduct exhaust port 37 is positioned in the side wall of the housing 31, it may offer advantages in terms of exhaust performance and installation ease of connection to the exhaust line.

As illustrated in FIG. 2, the exhaust unit 300 may be positioned in front of the injection unit 200 based on the substrate transport direction. This is because, during the processing process, the fluid is sprayed toward the substrate transport direction or in a direction perpendicular to the substrate transport direction. In particular, fluids such as cleaning solutions and drying gases may be sprayed toward the substrate transport direction. That is, during the processing process, the fluid may flow from a front end of the spray unit 200 toward an inlet gate of the processing chamber 100 through the substrate is transported, and accordingly the byproducts may flow along with the fluids.

The exhaust unit 300 and the substrate processing apparatus 1000 may vary the position of each of the inlet ports 39 that has a structure that partially opens the inflow space 33 into which the byproducts are introduced, thereby varying the exhaust position for exhausting the byproducts generated during the processing process. Accordingly, the exhaust unit 300 and the substrate processing apparatus 1000 may change the exhaust position to a desired position even when a situation occurs in which air flow, etc. changes during the processing process, so that byproducts may be exhausted under optimal conditions.

Hereinafter, an exhaust unit and a drying treatment apparatus for exhausting byproducts generated during a drying process of a cleaning solution sprayed onto a substrate will be described with reference to FIGS. 1 to 4, as examples of the exhaust unit and the substrate processing apparatus according to example embodiments.

First, referring to FIG. 1, a substrate treatment apparatus for drying a substrate, i.e., a drying treatment apparatus may include a process chamber 100, a transport unit 400, an injection unit 200, an exhaust unit 300, etc.

The process chamber 100 may be provide a processing space where a drying process is performed, and may include an inlet section for loading the substrate on one side wall and an outlet section for unloading the substrate on the other side wall.

The transport unit may be configured to transport the substrate by rotational driving of a roller in contact with a backside surface of the substrate, and may be configured to have a structure in which a plurality of rollers are arranged at regular intervals along the inlet section and the outlet section.

The injection unit 200 may be configured to inject a drying gas toward a substrate being transported to the process chamber 100 by the transport unit 400.

As illustrated in FIG. 2, the spray unit 200 may be arranged diagonally at a predetermined angle relative to a direction perpendicular to the substrate transport direction. In this case, the spray unit 200 may be disposed to have a length that covers the substrate from one end to the other end based on the diagonal arrangement. Accordingly, the spray unit 200 may be arranged to have a length longer than a width direction of the substrate perpendicular to the substrate transport direction.

As illustrated in FIG. 1, the spray unit 200 may be arranged to spray a drying gas toward the substrate while tilted at a predetermined angle toward the substrate transport direction. The spray unit 200 may be disposed to spray drying gases toward front and backside surfaces of the substrate, respectively. That is, the spray unit 200 may be arranged to have a predetermined angle between a horizontal direction in which the substrate is transported and a direction perpendicular to the horizontal direction, and may be provided to have a structure that is inclined at approximately several to several tens of angles.

The exhaust unit 300 may be provided to exhaust byproducts generated by spraying the drying gas during the drying treatment process to the outside of the process chamber 100. As illustrated in FIG. 1, the exhaust unit 300 may be provided to be positioned in front of the spray unit 200 with respect to the substrate transport direction, and in particular, may be provided to be disposed at both upper and lower portions of the process chamber 100.

Referring to FIG. 3, the exhaust unit 300 may include a housing 31, a byproduct inlet portion 35, and a byproduct exhaust portion 37. The housing 31 may provide an inflow space 33 into which byproducts are introduced. The byproduct inlet portion 35 may be provided on an open upper surface of the housing 31, and as illustrated in FIG. 2, the open upper surface of the housing 310 may be provided with a plurality of open regions (IR) in a checkerboard arrangement structure. Each of the plurality of open regions may have the same size. An inlet port 39 may be provided in one open region selected from the plurality of open regions, and the inlet portion may have the same size as the open region. Each of the plurality of inlet ports 39 may be provided to be selectively opened. In this way, the byproduct inlet portion 35 may be provided with the plurality of inlet ports 39 that partially open the inflow space 33 and may be selectively opened.

The byproduct exhaust portion 37 may be provided in a portion of a bottom surface (bottom wall) of the housing 31, and may be provided with a hole structure as shown in FIG. 2. Accordingly, the byproduct exhaust portion 37 may be configured to exhaust the byproduct introduced into the inflow space 33 to the outside through the hole provided in the portion of the bottom surface of the housing 31. The hole of the byproduct exhaust portion 37 may be configured to be connected to an exhaust line and a vacuum pump, etc., through which the byproduct introduced into the inflow space 33 may be vacuum exhausted.

Even though the inlet port 39 is used, byproducts must be introduced into the inflow space 33. Therefore, as shown in FIG. 4, a flow path 41 may be formed in the inlet port 39 to provide a path for the byproducts to flow into the inflow space 33. If the inlet ports 39 are simply opened to introduce the byproducts into the inflow space 33, the drying gas and the like may also flow into the inflow space 33, potentially altering the process conditions within the process chamber 100. Accordingly, the inlet port 39 may be provided with an opening/closing member for selectively opening the flow path 41.

As illustrated in FIG. 2, the inlet ports 39 may be individually installed to allow selective opening of four open regions (regions \textcircled{1}, \textcircled{2}, \textcircled{3}, and \textcircled{4}). However, when performing the drying treatment process, the process conditions such as the air flow and injection amount of the drying gas, etc. may be changed, and accordingly, the positions of the four inlet ports 39 may be changed such that the inlet ports 39 are installed in the changed open regions to cover the changed open regions.

The positioning of the inlet port 39 may be performed using a puzzle structure. For example, as illustrated in FIG. 3, the previously installed inlet port 39 may be lifted up from the open upper surface of the housing 31, and then the inlet port 39 may be moved and installed to cover an open region (IR) newly exposed by moving the puzzle-structured piece plates 36.

While the exhaust unit 300 and the substrate processing apparatus 1000 have been described using a drying processing apparatus as an example, example embodiments are not limited thereto. That is, if the structures of the process chamber 100, the injection unit 200, the transport unit 400, etc., are changed, the exhaust unit 300 and the substrate processing apparatus 1000 may be easily applied to a cleaning processing apparatus, a photoresist coating apparatus, R, G, B ink ejection apparatus, a developing apparatus, a thin film forming apparatus, a vacuum drying apparatus, etc.

The above exhaust unit and substrate processing apparatus according to example embodiments may be applied to exhaust byproducts generated during the manufacture of integrated circuit devices such as semiconductor devices and display devices. Accordingly, the exhaust unit and substrate processing apparatus according to example embodiments may be more easily applied to manufacture not only OLEDs and QLEDs, but also DRAMs, NANDs, system semiconductors, image sensors, and the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. An exhaust unit, comprising:
a housing configured to provide an inflow space into which byproducts generated during a substrate processing process are introduced;
a byproduct inlet portion including at least one inlet port provided in an open upper surface of the housing and having a structure that partially opens the inflow space so that the byproducts are introduced into the inflow space, the byproduct inlet portion including a plurality of piece plates that respectively cover open regions, excluding the open region in which the at least one inlet port is provided, among a plurality of open regions of the open upper surface of the housing; and
a byproduct exhaust portion having a hole structure provided on a portion of a lower surface of the housing so as to exhaust the byproducts introduced into the inflow space of the housing through the byproduct inlet portion, to the outside.

2. The exhaust unit of claim 1, wherein
the housing is disposed at a lower portion of the process chamber where the processing process is performed, the byproduct inlet portion is disposed at the lower portion of the process chamber toward the interior of the process chamber, and the byproduct exhaust portion is disposed at the lower portion of the process chamber toward the exterior, or/and
the housing is disposed at an upper portion of the process chamber where the processing process is performed, the byproduct inlet portion is disposed at the upper portion of the process chamber toward the interior of the process chamber, and the byproduct exhaust portion is disposed at the upper portion of the process chamber toward the exterior.

3. The exhaust unit of claim 1, wherein the plurality of open regions are provided to have a checkerboard arrangement.

4. The exhaust unit of claim 1, wherein the at least one inlet port is provided with a flow path that provides a path for the byproduct to flow into the inflow space, and the at least one inlet port has an opening/closing member that selectively opens and closes the flow path.

5. The exhaust unit of claim 4, wherein the plurality of open regions have the same size, and the inlet port has a size that covers each of the open regions of the same size.

6. A substrate processing apparatus, comprising:
a process chamber configured to provide a processing space for performing a processing process on a substrate;
a transport unit configured to transfer the substrate to the process chamber;
an injection unit configured to spray a fluid toward the substrate transferred to the process chamber by the transport unit; and
an exhaust unit configured to exhaust byproducts generated by spraying the fluid during the processing process, to the outside of the process chamber,
wherein the exhaust unit comprises:
a housing configured to provide an inflow space into which the byproducts are introduced;
a byproduct inlet portion including at least one inlet port provided in an open upper surface of the housing and having a structure that partially open the inflow space so that the byproducts are introduced into the inflow space, the byproduct inlet portion including a plurality of piece plates that are provided to cover open regions, excluding the open region in which the at least one inlet port is provided, among a plurality of open regions constituting the open upper surface of the housing; and
a byproduct exhaust portion having a hole structure provided in a portion of a lower surface of the housing so as to exhaust the byproduct introduced into the inflow space of the housing through the byproduct inlet portion, to the outside.

7. The substrate processing apparatus of claim 6, wherein the transport unit is configured to transfer the substrate by rotational driving of a roller in contact with a backside surface of the substrate, or to transfer the substrate while the substrate is levitated.

8. The substrate processing apparatus of claim 6, wherein:
the injection unit is configured to spray a fluid toward a front surface of the substrate, to spray a fluid toward a backside surface of the substrate, or to spray a fluid toward both of the front and backside surfaces of the substrate.

9. The substrate processing apparatus of claim 6, wherein:
the injection unit is arranged diagonally at a predetermined angle relative to a vertical direction perpendicular to the transport direction of the substrate, and is configured to have a length that covers from one end of the substrate to the other end in the diagonal arrangement.

10. The substrate processing apparatus of claim 6, wherein the injection unit is configured to inject a fluid toward the substrate while tilted at a predetermined angle toward the direction in which the substrate is transported.

11. The substrate processing apparatus of claim 6, wherein the exhaust unit is positioned in front of the injection unit with respect to the direction in which the substrate is transported.

12. The substrate processing apparatus of claim 6, wherein
the housing of the exhaust unit is disposed at a lower portion of the process chamber, the byproduct inlet portion is disposed at the lower portion of the process chamber toward the interior of the process chamber, and the byproduct exhaust portion is disposed at the lower portion of the process chamber toward the exterior, or/and
the housing is disposed at an upper portion of the process chamber, the byproduct inlet portion is disposed at the upper portion of the process chamber toward the interior of the process chamber, and the byproduct exhaust portion is disposed at the upper portion of the process chamber toward the exterior.

13. The substrate processing apparatus of claim 6, wherein the plurality of open regions in the exhaust unit are arranged to have a checkerboard arrangement.

14. The substrate processing apparatus of claim 6, wherein the at least one inlet port has a flow path formed therein that provides a path for the byproduct to flow into the inflow space, and the at least one inlet portion has an opening/closing member that selectively opens and closes the flow path.

15. The substrate processing apparatus of claim 14, wherein the plurality of open regions in the exhaust unit have the same size, and the inlet port has a size that covers each of the open regions of the same size.

16. A substrate processing apparatus, comprising:
a process chamber configured to provide a processing space in which a substrate is dried;
a transport unit configured to transfer the substrate to the process chamber, the transport unit configured to transfer the substrate by driving of a roller in contact with a backside surface of the substrate;
an injection unit configured to spray a drying gas toward the substrate transferred to the process chamber by the transport unit, the injection unit being arranged diagonally at a predetermined angle relative to a vertical direction perpendicular to the transport direction of the substrate, the injection unit configured to have a length that covers the substrate from one end to the other end in the diagonal arrangement, the injection unit configured to spray the drying gas toward the substrate while being tilted at a predetermined angle toward the direction in which the substrate is transported; and
an exhaust unit configured to exhaust byproducts generated by spraying the drying gas during the drying process, to the outside of the process chamber, the exhaust unit configured to be positioned in front of the spray unit with respect to the transport direction of the substrate,
wherein the exhaust unit comprises:
a housing configured to provide an inflow space into which the byproducts are introduced;
a byproduct inlet portion including at least one inlet port provided in an open upper surface of the housing and having a structure that partially open the inflow space so that the byproducts are introduced into the inflow space, the byproduct inlet portion including a plurality of piece plates that are provided to cover open regions, excluding the open region in which the at least one inlet port is provided, among a plurality of open regions constituting the open upper surface of the housing; and
a byproduct exhaust portion having a hole structure in a portion of a bottom surface of the housing so as to exhaust the byproduct introduced into the inflow space of the housing through the byproduct inlet portion, to the outside.

17. The substrate processing apparatus of claim 16, wherein the injection unit is configured to spray a fluid toward a front surface of the substrate, toward the backside surface of the substrate, or toward both of the front and backside surfaces of the substrate.

18. The substrate processing apparatus of claim 16, wherein:
the housing of the exhaust unit is disposed at a lower portion of the process chamber, the byproduct inlet portion is disposed at the lower portion of the process chamber toward the interior of the process chamber, and the byproduct exhaust is disposed at the lower portion of the process chamber toward the exterior, or/and
the housing is disposed at an upper portion of the process chamber, the byproduct inlet portion is disposed at the upper portion of the process chamber toward the interior of the process chamber, and the byproduct exhaust is disposed at the upper portion of the process chamber toward the exterior.

19. The substrate processing apparatus of claim 16, wherein the plurality of open regions of the exhaust unit are arranged to have a checkerboard arrangement.

20. The substrate processing apparatus of claim 16, wherein:
the plurality of open regions in the exhaust unit have the same size, and the inlet port is formed with a flow path that provides a path for the byproduct to flow into the inflow space, and the inlet port is sized to selectively cover each of the open regions of the same size.
